(19) United States
(12) Patent Application Publication
(10) Pub. No.: US 2008/0176477 A1
(43) Pub. Date: Jul. 24, 2008

(54) Method for manufacturing a display device

(75) Inventors: Tae-Hyung Hwang, Seoul (KR); Nam-Seok Roh, Seongnam-si (KR); Myung-Hwan Kim, Yongin-si (KR)

Correspondence Address: MACPHERSON KWOK CHEN & HEID LLP, 2033 GATEWAY PLACE, SUITE 400, SAN JOSE, CA, 95110, US

(73) Assignee: Samsung Electronics Co., Ltd.

(21) Appl. No.: 11/982,065

(22) Filed: Oct. 31, 2007

(30) Foreign Application Priority Data
Jan. 19, 2007 (KR) 10-2007-0006000
May 8, 2007 (KR) 10-2007-0044537

(51) Int. Cl. H01J 9/00

(52) U.S. Cl. 445/24

(57) ABSTRACT

A method of manufacturing a display device is provided, which includes: forming a buffer layer on a supporting plate; forming a flexible substrate layer on the supporting plate and the buffer layer; forming at least one thin film on the flexible substrate layer; forming a protective layer covering the at least one thin film; forming a plurality of through-holes to expose the buffer layer; removing the buffer layer by injecting an etchant into the through-holes; removing the protective layer; and separating the flexible substrate layer from the supporting plate. According to the present invention, misalignment of the thin films due to the deformation of the plastic substrate may be prevented such that the production time may be minimized, thereby improving productivity of the display device.

### CROSS-REFERENCE TO RELATED APPLICATIONS

This application claims priority to and the benefit of Korean Patent Application No. 10-2007-0006000 filed on Jan. 19, 2007, and Korean Patent Application No. 10-2007-0044537 filed on May 8, 2007, in the Korean Intellectual Property Office, the entire contents of which are incorporated herein by reference.

### BACKGROUND OF THE INVENTION

(a) Field of the Invention

The present invention relates to a method for manufacturing a display device, and more particularly, to a method for manufacturing a flexible display device.

(b) Description of the Related Art

A liquid crystal display (LCD), an organic light emitting device (OLED), and an electrophoretic display (EPD) are among the most widely used flat panel displays that are currently supplanting the conventional cathode ray tube.

However, because the liquid crystal display and the organic light emitting display include fragile and heavy glass substrates, they are not suitably portable or advantageous for a large scale display.

Display devices using a plastic substrate that is flexible, light and strong have recently been under development.

When using the plastic substrate instead of a glass substrate, a printing process may be used to form the flexile display and accordingly the manufacturing cost may be reduced, and the flexible display using the plastic substrate may be manufactured by a roll-to-roll process as opposed to a general sheet unit process. Accordingly, production costs may be minimized due to large scale production.

However, because the plastic substrate is very sensitive to temperature, the manufacturing process using the plastic substrate is difficult because it must be executed at room temperature.

Also, to prevent contraction and expansion of the plastic substrate, the plastic substrate is adhered to a solid supporting plate using an adhesive agent or a synthetic resin is coated on the solid supporting plate to form the plastic substrate, and then a plurality of thin films are formed thereon. Next, the solid supporting plate is separated from the plastic substrate using a laser or chemicals. However, it is difficult for the solid supporting plate to be separated from the plastic substrate due to deformation of the plastic substrate or the adhesive agent by heat generated when forming the thin films.

Furthermore, misalignment of the thin films or contact holes formed in the thin films is generated due to the contraction and expansion of the plastic substrate such that the electrical characteristics or the reliability of the display device may be deteriorated.

### SUMMARY OF THE INVENTION

In light of the foregoing, there is a need to improve electrical characteristics and reliability of the display device by preventing the misalignment due to the contraction and expansion of the plastic substrate.

A method of manufacturing a display device is provided, which includes: forming a buffer layer on the supporting plate; forming a flexible substrate layer on the supporting plate and the buffer layer; forming at least one thin film on the flexible substrate layer; forming a protective layer covering the at least one thin film; forming a plurality of through-holes to expose the buffer layer; removing the buffer layer by injecting an etchant into the through-holes; removing the protective layer; and separating the flexible substrate layer from the supporting plate.

The method may further comprise an an etch promotion layer before forming the buffer layer.

The formation of the through-holes may further comprise forming a plurality of through-holes to expose the etch promotion layer.

The removal the buffer layer may further comprise removing the etch promotion layer.

The etch promotion layer may include a highly polymerized compound that gelates or swells.

The highly polymerized compound may include at least one of polyethylene and polyvinylchloride.

The etch promotion layer may have air gaps, and the etch promotion layer may include at least one of polyallyamine, polydiallyldiethyl ammonium chloride, polyacrylic acid, polyimide, polystyrene, and a urethane polymer.

The formation of the etch promotion layer may include forming a mixture of at least two polymers that are not dissolved by each other; coating the mixture on the supporting plate; hardening the coated mixture; and removing one or more of the polymers by using a solvent that dissolves at least one of the polymers.

The formation of the etch promotion layer may include coating a solvent including inorganic matter particles and a highly polymerized compound on the supporting plate, and sintering the solvent at a low temperature.

The inorganic matter particles may include at least one of titanium dioxide (TiO₂), indium tin oxide (ITO), indium zinc oxide (IZO), an azo group, and GaOₓ.

The formation of the etch promotion layer may include sequentially forming polyacrylic and polyallylamine on the supporting plate, and exposing the supporting plate to an acidic vapor.

The formation of the etch promotion layer may include the deposition of a urethane polymer on the supporting plate by sputtering.

The formation of the etch promotion layer may include coating the highly polymerized compound that gelates and swells and a highly polymerized compound having absorptiveness and solubility, and only dissolving the highly polymerized compound having absorptiveness and solubility.

The protective layer may include photosensitive material.

The buffer may be made of a transparent conductive layer including ITO, IZO, or a-ITO.

The thickness of the buffer may be in the range of 100 to 1000 angstroms.

The thickness of the flexible substrate layer may be in the range of 10 to 200 microns.

The through-holes may be formed by using a laser.

The method may further include removing the circumferential portion of among the flexible substrate layer before separating the flexible substrate layer from the supporting plate.

The removal of the circumferential portion of the flexible substrate may comprise irradiating a laser beam on the flexible substrate in a direction which is perpendicular to a surface of the supporting plate. The supporting plate may be soaked in a bath including an etchant for etching the buffer layer.

A method of manufacturing a display device is provided, which includes: forming a buffer layer having an upper surface, a lower surface, and side surfaces on a supporting plate; forming a flexible substrate layer on the supporting plate and the buffer layer; forming at least one thin film on the flexible substrate layer; removing the buffer layer by contacting one of the upper, lower, and side surfaces with an etchant; and separating the flexible substrate layer from the supporting plate.

The method may further include forming a thin film that absorbs the etchant on at least one of the upper and lower surfaces.

The speed of absorbing the etchant by the thin film may be faster than the speed of absorbing the etchant by the side surfaces of the buffer layer.

### BRIEF DESCRIPTION OF THE DRAWINGS

The above and other advantages of the present invention will become more apparent in light of the embodiments described below in detail with reference to the accompanying drawings, in which:

FIG. 1 is a perspective view of a display device according to an embodiment of the present invention;

FIG. 2 is a sectional view of the display device shown in FIG. 1 taken along the line II-II′;

FIG. 3 is a perspective view of a panel for a display device in a first step of a manufacturing method thereof according to an embodiment of the present invention;

FIG. 4 is a perspective view of the panel for a display device in the step following that of FIG. 3;

FIG. 5 is a perspective view of the panel for a display device in the step following that of FIG. 4;

FIG. 6 is a sectional view of the panel for a display device shown in FIG. 5 taken along the line VI-VI;

FIG. 7 is a perspective view of the panel for a display device in the step following that of FIG. 5;

FIG. 8 is a sectional view of the panel for a display device shown in FIG. 7 taken along the line VIII-VIII′;

FIG. 9 is a perspective view of the panel for a display device in the step following that of FIG. 7;

FIG. 10 is a sectional view of the panel for a display device shown in FIG. 9 taken along the line X-X′;

FIG. 11 is a perspective view of a panel for a display device in first step of a manufacturing method thereof according to another embodiment of the present invention;

FIG. 12 is a perspective view of the panel for a display device in the step following that of FIG. 11;

FIG. 13 is a perspective view of the panel for a display device in the step following that of FIG. 12;

FIG. 14 is a sectional view of the panel for a display device shown in FIG. 13 taken along the line XIV-XIV;

FIG. 15 is a perspective view of the panel for a display device in the step following that of FIG. 13;

FIG. 16 is a sectional view of the panel for a display device shown in FIG. 15 taken along the line XVII-XVII;

FIG. 17 is a sectional view of the panel for a display device shown in FIG. 15 taken along the line XVII-XVII in the step following that of FIG. 16;

FIG. 18 is a view showing a penetration direction of an etchant in FIG. 17;

FIG. 19 is a layout view of a TFT array panel for an electrophoretic display (EPD) according to another embodiment of the present invention; and

FIG. 20 is a sectional view of the TFT array panel shown in FIG. 19 taken along the lines XX-XX.

### DETAILED DESCRIPTION OF EMBODIMENTS

The present invention is described more fully hereinafter with reference to the accompanying drawings, in which preferred embodiments of the invention are shown. The present invention may, however, be embodied in many different forms and should not be construed as limited to the embodiments set forth herein.

In the drawings, the thickness of layers, films, and regions are exaggerated for clarity. Like numerals refer to like elements throughout. It will be understood that when an element such as a layer, film, region, or substrate is referred to as being “on” another element, it can be directly on the other element or intervening elements may also be present. In contrast, when an element is referred to as being “directly on” another element, there are no intervening elements present.

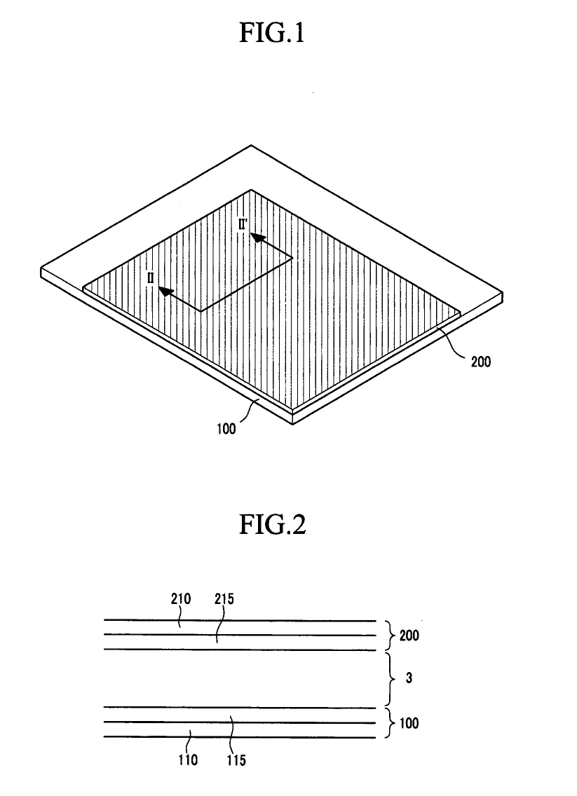

Now, a display device according to embodiments of the present invention will be described with reference to FIGS. 1 and 2.

FIG. 1 is a perspective view of a display device according to an embodiment of the present invention, and FIG. 2 is a sectional view of the display device shown in FIG. 1 taken along the line II-II.

Referring to FIGS. 1 and 2, a display device according to the embodiment of the present invention includes a lower panel 100 and an upper panel 200 facing the lower panel 100, and an electro-optical active layer 3 interposed between the lower and upper panels 100 and 200.

The lower and upper panels 100 and 200 respectively include substrates 110 and 210 and thin films 115 and 215, and may switche the positions.

The substrates 110 and 210 are preferably made of polyimide or polyether sulfone (PES). These materials have characteristics such as a good heat-resistant property and a smaller coefficient of thermal expansion than the plastic such that the bends and the contraction intensity are small. One of the two substrates 110 and 210 may be omitted.

The thin films 115 and 215 may include a plurality of switching elements (not shown), a plurality of electrodes (not shown), a plurality of capacitors (not shown), and a plurality of signal lines (shown).

The electro-electro-optical active layer 3 to convert electrical signals to optical signals may be an electrophoretic material, a liquid crystal layer, and an organic light emitting layer.

The display device may additionally include at least one of a polarizer, a compensation film, a light guiding plate, and a diffusing plate to improve and control light characteristics, they are mainly used to the liquid crystal display.

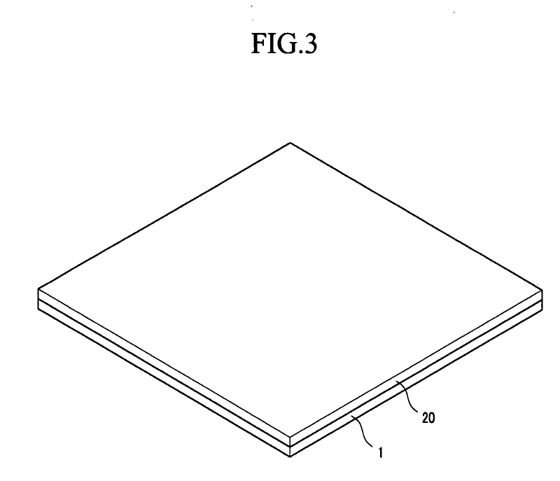

A method of manufacturing the panel for the display device according to embodiments of the present invention is described below with reference to FIGS. 3-10 as well as FIGS. 1 and 2.

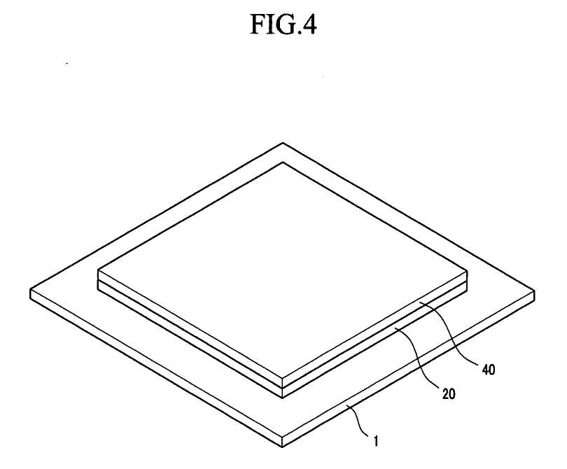

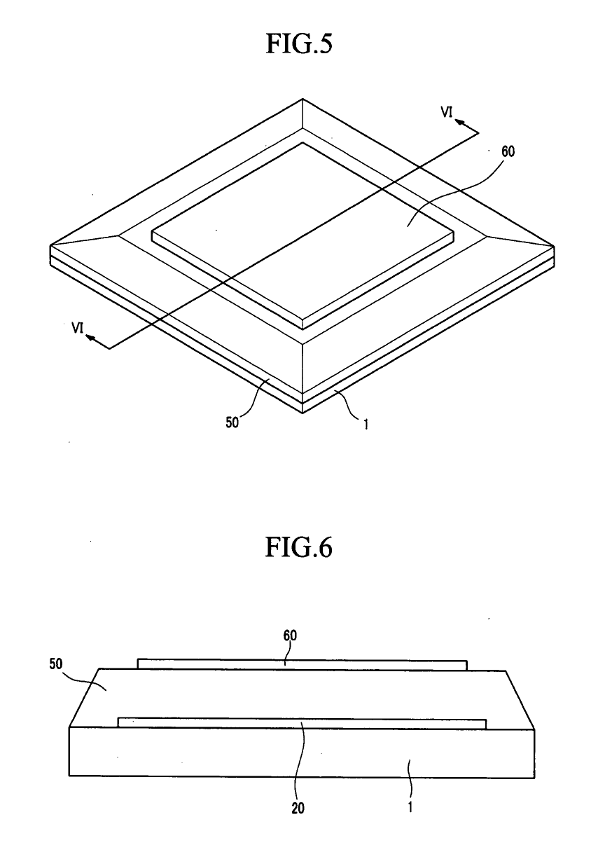

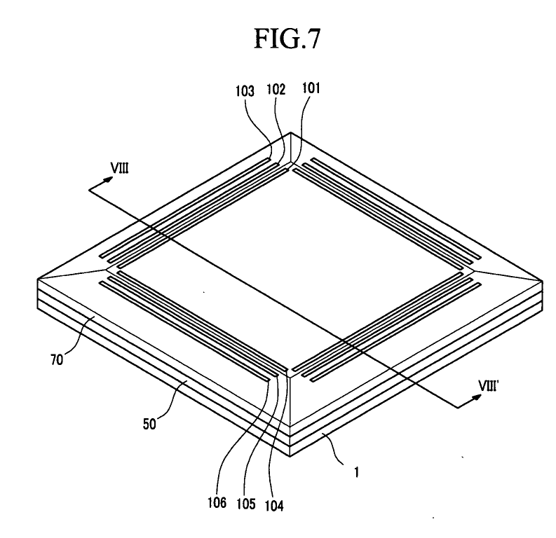

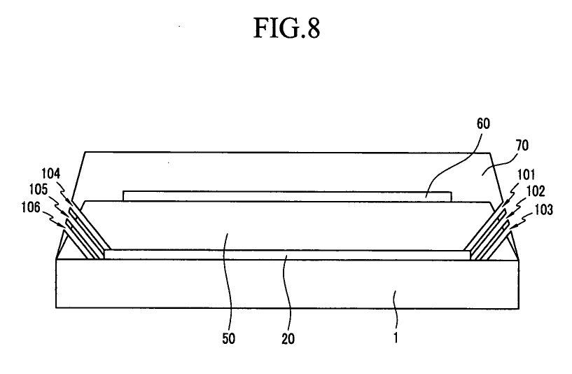

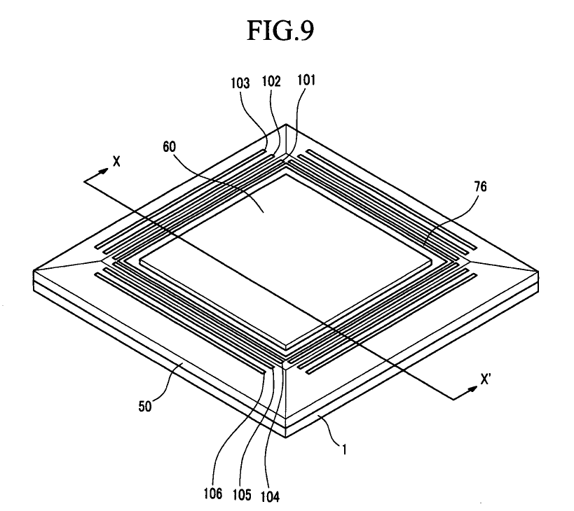

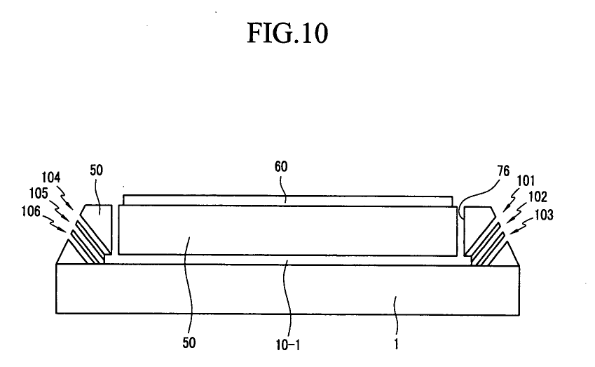

FIG. 3 is a perspective view of a panel for a display device in a first step of a manufacturing method thereof according to an embodiment of the present invention, FIG. 4 is a perspective view of the panel for a display device in the step following that of FIG. 3, FIG. 5 is a perspective view of the panel for a display device in the step following that of FIG. 4, FIG. 6 is a sectional view of the panel for a display device shown in FIG. 5 taken along the line VI-VI, FIG. 7 is a perspective view of the panel for a display device in the step following that of FIG. 5, FIG. 8 is a sectional view of the panel for a display device shown in FIG. 7 taken along the line VIII-VIII, FIG. 9 is a perspective view of the panel for a display device in the step following that of FIG. 7, and FIG. 10 is a sectional view of the panel for a display device shown in FIG. 9 taken along the line X-X.

Referring to FIG. 3, a buffer layer 20 made of a conductive material such as indium tin oxide (ITO), amorphous indium tin oxide (a-ITO), or indium zinc oxide (IZO), and a metal, is deposited on a supporting plate 1 made of a solid material such as glass by using sputtering, PECVD. It is preferable that the thickness of the buffer layer 20 is in the range of 100 to 1000 angstroms.

Referring to FIG. 4, a photoresist layer 40 is formed on the central portion of the buffer layer 20 except at the outer portion of the buffer layer 20, and the buffer layer 20 is etched using the photoresist layer 40 as an etch mask.

Next, referring to FIGS. 5 and 6, the photoresist layer 40 is removed, and a flexible substrate layer 50 completely covering the buffer layer 20 is formed on the buffer layer 20.

The flexible substrate layer 50 is preferably made of the material having the characteristics such as a good heat-resistant property and a smaller coefficient of thermal expansion than the plastic such that the stoop and the contraction intensity are small such as polyimide and polyether sulfone (PES). It is preferable that the thickness of the flexible substrate layer 50 is in the range of 10 to 200 microns.

Next, thin films 60 are formed on the flexible substrate layer 50 inside the region where the buffer layer 20 is formed.

The thin films 60 may include a plurality of switching elements (not shown), a plurality of electrodes (not shown), a plurality of capacitors (not shown), and a plurality of signal lines (shown). The thin films 60 are disposed on the buffer layer 20 and occupy the smaller region than the buffer layer 20. The thin films 60 may include a plurality of conductive layers (not shown) and at least one insulating layer formed between the conductive layers, and is formed by repeated forming and patterning processes.

Here, heat may be generated in the formation process of the thin films 60, but because the coefficient of thermal expansion of the flexible substrate layer 50 made of polyimide and polyether sulfone (PES) is small, the stoop and the contraction are not generated in the formation process of the thin films 60. Accordingly, the electrical characteristics and the reliability of the display device may be improved.

Here, because the buffer layer 20 is completely covered by the flexible substrate 50, the buffer layer 20 is not removed in the patterning process for forming the thin films 60.

Referring to FIGS. 7 and 8, a protecting layer 70 is formed on the thin films 60 and the flexible substrate layer 50. It is preferable that the thickness of the protecting layer 70 is more than 1 micron. Next, a plurality of penetration holes 101, 102, 103, 104, 105, and 106 are formed in the protective layer by using a laser for exposing the buffer layer 20. The penetration holes 101, 102, 103, 104, 105, and 106 are disposed in the portion of the protective layer 70 corresponding to the four edges of the buffer layer 20, and are inclined toward the four edges of the buffer layer 20 from the four sides of the flexible substrate layer 50.

Next, referring to FIGS. 9 and 10, the supporting plate 1 is soaked in a bath including an etchant for removing the buffer layer 20. Here, the etchant permeates the inside of the buffer layer 20 thought the penetration holes 101, 102, 104, and 105 such that the buffer layer 20 is removed and a space 10-1 corresponding to the space formerly occupied by buffer layer 20 is formed. Here, the protective layer 70 prevents the thin films 60 from being removed by the etchant.

Next, the protective layer 70 is removed, and a slot 76 is formed to extend to the space 10-1 by using a laser. Slot 76 is disposed between penetration holes 101, 104 and the boundary of the thin films 60, and extends around the perimeter of flexible substrate and thin films 60. Slot 76 is connected to the space where the buffer layer 20 is removed such that the supporting plate 1 is exposed. However, slot 76 does not expose the thin films 60.

Accordingly, because slot 76 is connected to the space 10-1 where the buffer layer 20 is removed, the portion of the flexible substrate layer 50 is separated from the supporting plate 1 such that the panel having the flexible substrate layer 50 and the thin films 60 is completed for a display device.

In general, for forming a complete panel, a flexible substrate is adhered on a supporting plate using an adhesive and then thin films are formed on the flexible substrate, or a flexible resin is formed on a supporting plate using spin coating for forming a flexible substrate and then thin films are formed. Next, the panel is separated from the supporting plate by applying heat or physical force. However, the flexible substrate becomes curved or contracted by the heat or physical force such that the arrangements of the thin films or contact holes are misaligned, and accordingly the characteristics or the reliability of the EPD are deteriorated.

In this embodiment, the buffer layer 20 is formed under the flexible substrate layer 50, and the etchant is penetrated through the penetration holes 101-106 for removing the buffer layer 20. Next, slot 76 is formed by a laser beam extending to the space 10-1 formed by the removal of the buffer layer 20 is formed such that the flexible substrate layer 50 is separated from the supporting plate 1. Therefore, a heating process which was required in the prior art for separating the flexible substrate adhered to the supporting plate is not needed. Accordingly, the misalignment of the thin films due to the contraction of the plastic substrate may be prevented, thereby improving the characteristics of, and the reliability of the EPD.

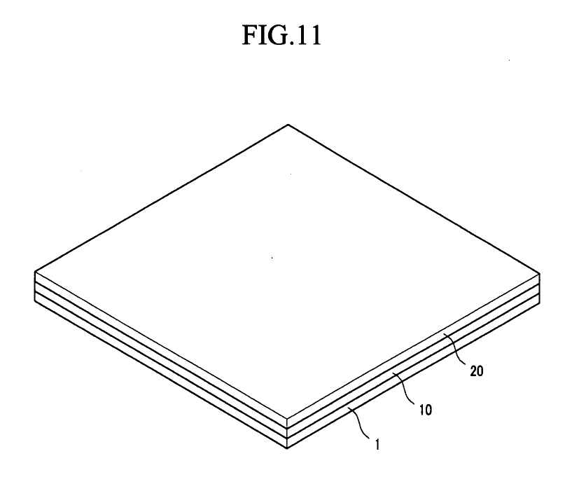

An alternative method of manufacturing the panel for the display device according to embodiments of the present invention is described below with reference to FIGS. 11-18 as well as FIGS. 1 and 2.

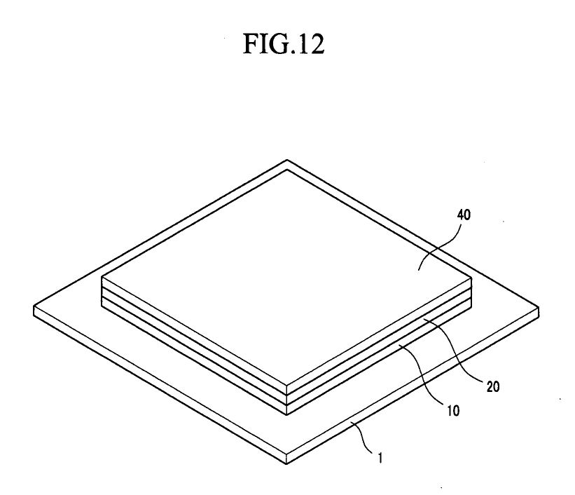

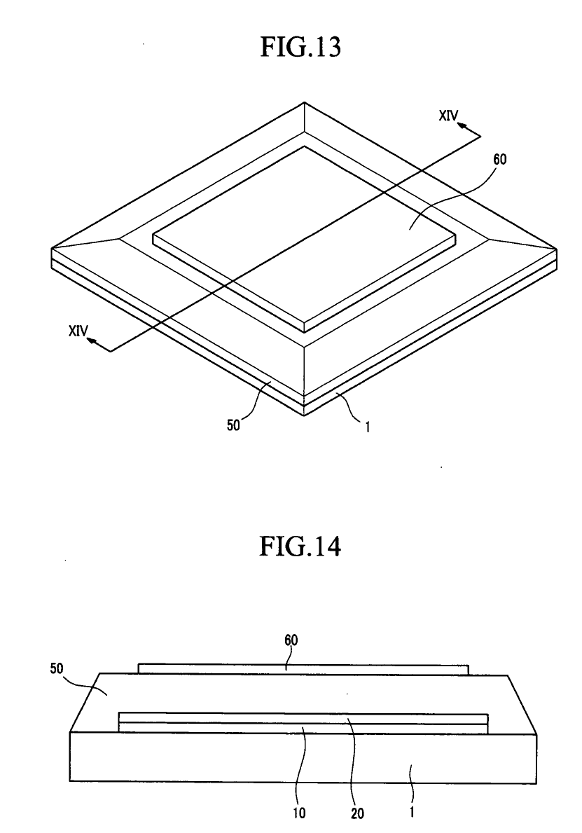

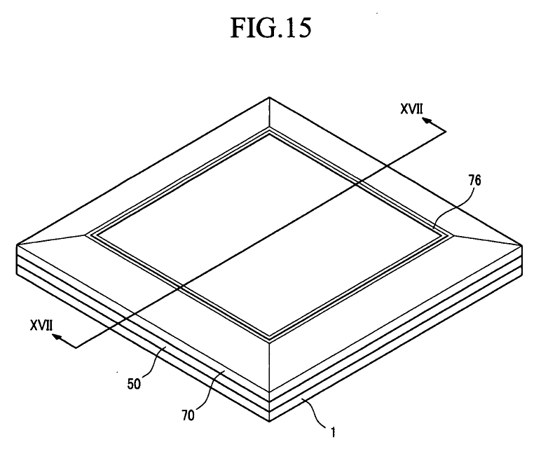

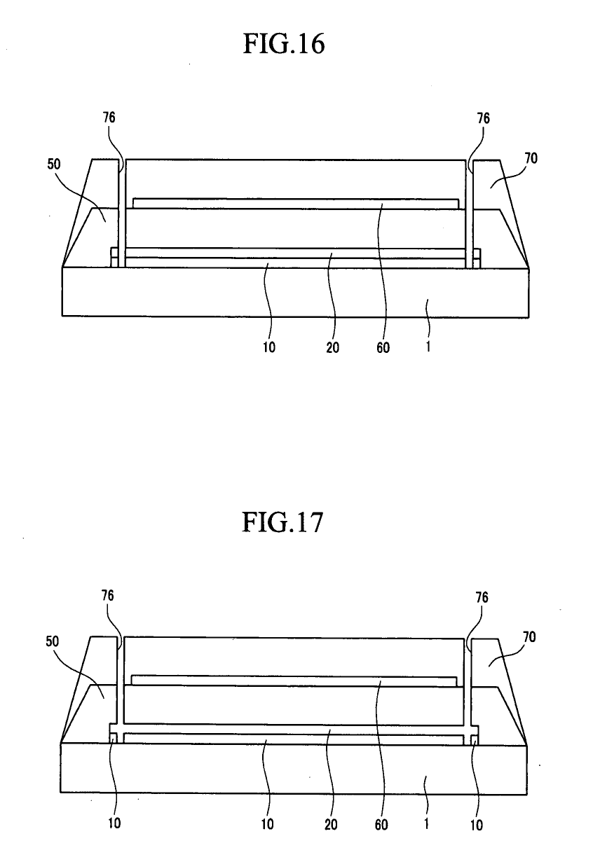

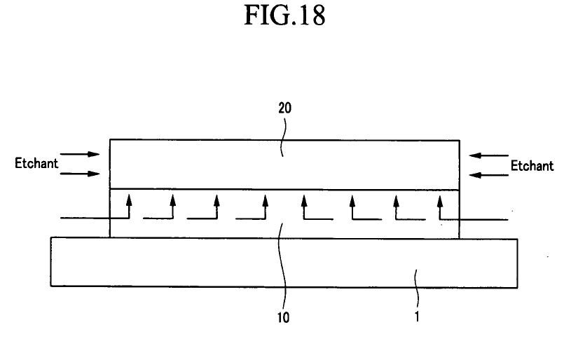

FIG. 11 is a perspective view of a panel for a display device in a first step of a manufacturing method thereof according to another embodiment of the present invention, FIG. 12 is a perspective view of the panel for a display device in the step following that of FIG. 11, FIG. 13 is a perspective view of the panel for a display device in the step following that of FIG. 12, FIG. 14 is a sectional view of the panel for a display device shown in FIG. 13 taken along the line XIV-XIV, FIG. 15 is a perspective view of the panel for a display device in the step following that of FIG. 13, FIG. 16 is a sectional view of the panel for a display device shown in FIG. 15 taken along the line XVII-XVII, FIG. 17 is a sectional view of the panel for a display device shown in FIG. 9 taken along the line XVII-XVII in the step following that of FIG. 16, and FIG. 18 is a view showing a penetration direction of an etchant in FIG. 17.

Referring to FIGS. 11 to 18, a layered structure according this embodiment is the same as the layered structure of FIGS. 3 to 10. Accordingly, the same numeral references are used and the descriptions of the same layers may be omitted.

Referring to FIG. 11, an etch promotion layer 10 is formed on a supporting plate 1. The etch promotion layer 10 is preferably made of a polymer having porosity and gelation and swelling characteristics. In the case of porosity of the etch promotion layer 10, the size of the air gap is in the range of about 1 nm to 10 microns, and the etch promotion layer 10 is preferably made of an organic material of a highly polymerized compound, an inorganic material, or a mixture including an organic material and an inorganic material. Furthermore, the etch promotion layer 10 may be made of a material that speedily absorbs an etchant.

Good examples of the highly polymerized compound having gelation and swelling characteristics are polyethylene and polyvinylchloride, and the etch promotion layer 10 may formed by spin coating or dripping.

Good examples of the etch promotion layer 10 made of the highly polymerized compound having porosity are polyallyamine, polydiallyldiethyl ammonium chloride, polyacrylic acid, polyimide, polystyrene, and a urethane polymer.

Good examples of the formation of the etch promotion layer 10 having porosity are electro-spinning, spin coating, and sintering.

In the case of using electro-spinning, a voltage is applied to the supporting plate 10 and an electrode (not shown) contacted with a solvent in which high molecules are solved and provided by a device such as a nozzle for supplying the solvent. In this case, the high molecule solvent is injected with a spiral shape and is coated on the supporting plate 10 with a fibrous tissue shape by an electrical field generated between the supporting plate 10 and the electrode. The etch promotion layer 10 formed by this method has air gaps, and the size of the air gaps may be controlled by the density of the high molecule solvent, the distance between the supporting plate 1 and the electrode of the device for supplying the high molecule solvent, and the magnitude of the applied voltage. The thickness of the etch promotion layer 10 may be controlled by the time of spraying the high molecule solvent.

In the case of using spin coating, at least two polymers that do not dissolve each other such as polyimide and polystyrene are mixed with a liquid. Next, the liquid is coated on the supporting plate 1 and hardened to form a layer. A phase separation phenomena of a nano or micro degree is generated in this layer, and it may have lamella, sphere, and rod structures in three dimensions. Theses structures may be changed according to a rate of a polymer solute, the kind of solvent, process time, and process temperature. Then, the layer having the phase separation phenomena is soaked in the solvent to dissolve one of the two polymers, namely one of polyimide and polystyrene, such that one polymer of polyimide and polystyrene is removed and the air gaps are formed in the layer. For example, chloroform, ethylacetate, and benzene may be used to remove polystyrene.

In the case of using sintering, an etch promotion layer 10 preferably made of a mixture including an organic material and an inorganic material is formed. Here, a solvent including inorganic matter particles with a size of less than nanometers or micrometers and a highly polymerized compound is coated on the supporting plate 1 using spin coating. The inorganic matter particles are preferably made of a metal oxide such as titanium dioxide (TiO₂), indium tin oxide (ITO), indium zinc oxide (IZO), an azo group, and GaOₓ with a lower cost. In this process, the thickness of the etch promotion layer 10 may be controlled by the density of the highly polymerized compound and the velocity of the spin coating, and the size of an air gap may be controlled by the size and the distribution of the particles.

The etch promotion layer 10 having porosity may be formed by various methods in addition to this method.

For example, to form the etch promotion layer 10, polyacrylic and polyallylamine may be sequentially formed on the supporting plate 1, then are exposed to acidic vapor, or a urethane polymer may be deposited on the supporting plate 1. Furthermore, a polymer used in the lithography process such as polyimide as a photoresist layer may be deposited and irradiated by ultraviolet rays or visible rays, and then the polymer may be etched to form air gaps.

Finally, the highly polymerized compound having gelation and swelling characteristics and the highly polymerized compound having absorptiveness and solubility are mixed, and are formed on the supporting plate 1. Then, only the highly polymerized compound having absorptiveness and solubility is dissolved to form an etch promotion layer 10 having porosity.

Next, a buffer layer 20 made of a conductive material such as indium tin oxide (ITO) or indium zinc oxide (IZO) and a metal is deposited on the etch promotion layer 10 by using sputtering, or PECVD.

Referring to FIG. 12, a photoresist layer 40 is formed on the central portion of the buffer layer 20 except for the outer portion of the buffer layer 20, and the buffer layer 20 and the etch promotion layer 10 are etched using the photoresist layer 40 as an etch mask. It is preferable that the remaining portion of the etch promotion layer 10 is the same as or larger than the remaining portion of the buffer layer 20.

Unlike this method, the etch promotion layer 10 and the buffer layer 20 may be patterned using different masks, and at least one of the etch promotion layer 10 and the buffer layer 20 may be patterned using a different method such as by using laser in the place of the photolithography.

Next, referring to FIGS. 13 and 14, the photoresist layer 40 is removed, and a flexible substrate layer 50 is formed on the buffer layer 20 and the supporting plate 1.

The flexible substrate layer 50 is preferably made of the material having the characteristics such as a good heat-resisting property and a smaller coefficient of thermal expansion than the plastic such that the stoop and the contraction intensity are small, such as polyimide and polyether sulfone (PES). It is preferable that the flexible substrate layer 50 completely covers the buffer layer 20 and the etch promotion layer 10.

Next, thin films 60 are formed on the flexible substrate layer 50.

The thin films 60 may include a plurality of thin film transistors (not shown), a plurality of electrodes (not shown), and a plurality of capacitors (not shown). The thin films 60 are disposed on the buffer layer 20 and occupy a smaller region than the buffer layer 20. The thin films 60 may include a plurality of conductive layers (not shown) and at least one insulating layer formed between the conductive layers, and is formed by repeated forming and patterning processes.

Here, the heat may be generated in the formation process of the thin films 60, because the coefficient of thermal expansion of the flexible substrate layer 50 made of polyimide and polyether sulfone (PES) is small, the stoop and contraction are not generated in the formation process of the thin films 60. Accordingly, the electrical characteristics and the reliability of the display device may be improved.

Here, because the buffer layer 20 is completely covered by the flexible substrate layer 50, the buffer layer 20 and the etch promotion layer 10 are not removed in the patterning process for forming the thin films 60.

Referring to FIGS. 15 and 16, a protective layer 70 is formed on the thin films 60 and the flexible substrate layer 50, and a slot 76 is formed in the protective layer 70 by using a laser.

Slot 76 is formed to extend around the periphery of the thin films 60. Slot 76 is extended in the protective layer 70 and the flexible substrate layer 50 such that it exposes the buffer layer 20 and the etch promotion layer 10. However, slot 76 does not expose the thin films 60.

Next, referring to FIG. 17, the supporting plate 1 and associated structures are soaked in a bath including an etchant for removing the buffer layer 20. Here, the etchant permeates to the buffer layer 20 and the etch promotion layer 10 though the through hole 76. Referring to FIG. 18, the etchant continuously attacks the sides of the buffer layer 20, and simultaneously penetrates the etch promotion layer 10 such that the etchant also attacks the lower surface of the buffer layer 20.

As above-described, the etch promotion layer 10 has porosity and gelation or swelling characteristics.

When the etch promotion layer 10 has porosity, because the etch promotion layer 10 has a plurality of holes having the function for moving the etchant to the inside portion, the etchant arrives at the inside portion of the etch promotion layer 10 with a faster speed than etch speed of the side of buffer layer 20.

When the etch promotion layer 10 has gelation or swelling characteristics, the etch promotion layer 10 does not have a plurality of holes due to the higher density than the highly polymerized compound with porosity, but the etch promotion layer with gelation or swelling characteristics has faster absorption than the different material.

Firstly, the material having a gelation characteristic is preferably made of a cross-linking polymer such as thermal-hardening plastic. The cross-linking polymer is not melted in the etchant, but quickly absorbs the etchant such that the bulk of the etch promotion layer 10 is increased.

Secondly, the material having a swelling characteristic is preferably made of a polymer with random coil shapes such as an entangled thread skein, and also quickly absorbs the etchant. If the etchant penetrates the material, the coil of the polymer get loose such that the bulk of the etch promotion layer 10 is increased by the swelling. This polymer may be melted in the etchant, or not, when the etchant has high solubility for the polymer, the swelling is continuously generated until the polymer is completely melted in the etchant.

By these characteristics of the etch promotion layer 10, the etchant arrives at the inside portion of the etch promotion layer 10 with a faster speed than the etch speed of the side of the buffer layer 20 such that the etchant also attacks the lower surface of the buffer layer 20. Accordingly, the etchant is contacted with the side and the lower surfaces of the buffer layer 20 by the etch promotion layer 10, and the buffer layer 10 may be speedily removed in comparison with the case in which the etchant attacks only the side of the buffer layer 20.

As a result, because the buffer layer 20 is exposed to the etchant through the etch promotion layer 10, the buffer layer 10 may be effectively removed in a short time in comparison with the case in which the etchant etches the buffer layer 20 with the etch promotion layer 10.

After removing the buffer layer 20 by this method, the thin films 60 and the protective layer 70 thereon as well as the flexible substrate layer 50 are separated from the supporting plate 1 such that one of two panels 100 and 200 is completed as shown in FIGS. 1 and 2.

Finally, the protective layer 70 is removed using an organic solvent.

The positions of the buffer layer 20 and the etch promotion layer 10 may be exchanged, and the etch promotion layer 10 may be formed on and under the buffer layer 20.

Therefore, a heat process for separating the flexible substrate adhered to the supporting plate is not required in the embodiments of the present invention. Accordingly, the misalignment of the thin films due to the contraction of the plastic substrate may be prevented, thereby improving the characteristics and the reliability of the display device.

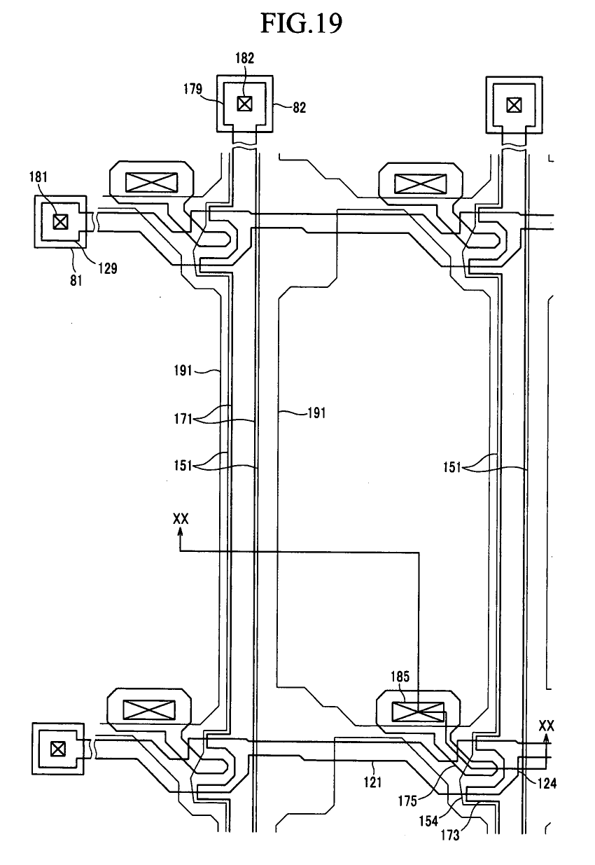

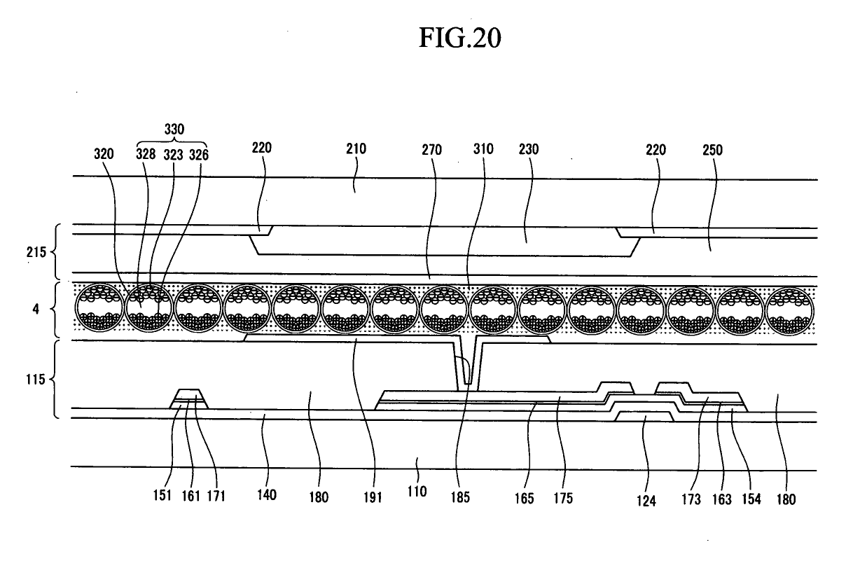

On the other hand, an electrophoretic display (EPD) using an electrophoretic material as the electro-optical active layer 3 may be an example of the display device, and the electrophoretic display (EPD) will be described in detail with reference to FIGS. 19 and 20.

FIG. 19 is a layout view of a TFT array panel for an electrophoretic display (EPD) according to another embodiment of the present invention, and FIG. 20 is a sectional view of the TFT array panel shown in FIG. 19 taken along the lines XX-XX.

An EPD according to this embodiment includes a lower panel 100, an upper panel 200, and an electrophoretic layer 4 formed between the panels 100 and 200.

The lower panel 100 includes a substrate 110 and thin films 115, and the upper panel 200 includes a substrate 210 and thin films 215.

Firstly, the thin films 115 of the lower panel 100 will be described in detail.

A plurality of gate lines 121 for transmitting gate signals extending substantially in a transverse direction are formed on the substrate 110. Each gate line 121 includes a plurality of portions forming a plurality of gate electrodes 124, and an end portion 129 having a large area for contact with another layer or an external device.

A gate insulating layer 140 preferably made of silicon nitride (SiNₓ) is formed on the gate lines 121, and a plurality of semiconductor stripes 151 and a plurality of ohmic contact stripes and islands 161 and 165 are formed on the gate insulating layer 140. A plurality of data lines 171 and a plurality of drain electrodes 175 separated from the data lines 171 are formed on the ohmic contacts 161 and 165 and the gate insulating layer 140.

The semiconductor stripes 151 are preferably made of hydrogenated amorphous silicon (abbreviated to “a-Si”) or polysilicon, and the ohmic contact stripes and islands 161 and 165 are preferably made of silicide or n+hydrogenated a-Si heavily doped with an n-type impurity such as phosphorous. Each semiconductor stripe 151 extends substantially in the longitudinal direction and has a plurality of projections 154 branched out toward the gate electrodes 124, and each ohmic contact stripe 161 has a plurality of projections 163. The projections 163 and the ohmic contact islands 165 are located in pairs on the projections 154 of the semiconductor stripes 151.

The data lines 171 transmit data voltages, and each data line 171 includes an end portion 179 having a large area for contact with another layer or an external device, and a plurality of source electrodes 173 projecting toward the drain electrodes 175. Each drain electrode 175 includes an end portion having a large area for contact with another layer, and another end portion disposed on a gate electrode 124 and partly enclosed by a source electrode 173.

Each set of a gate electrode 124, a source electrode 173, and a drain electrode 175 along with a projection 154 of a semiconductor stripe 151 form a TFT having a channel formed in the semiconductor projection 154 disposed between the source electrode 173 and the drain electrode 175.

The ohmic contacts 161 and 165 are interposed only between the underlying semiconductor stripes 151 and the overlying data lines 171 and the overlying drain electrodes 175 thereon, and reduce the contact resistance therebetween. The semiconductor stripes 151 include a plurality of exposed portions, which are not covered with the data lines 171 and the drain electrodes 175, such as portions located between the source electrodes 173 and the drain electrodes 175.

A passivation layer 180 is formed on the data lines 171, the drain electrodes 175, and the exposed portions of the semiconductor stripes 151. The passivation layer 180 is preferably made of an inorganic insulator such as silicon nitride or silicon oxide or an organic material having a good flatness characteristic, and the passivation layer 180 may have a double-layered structure including a lower inorganic film and an upper organic film.

The passivation layer 180 has a plurality of contact holes 182 and 185 exposing the end portions 179 of the data lines 171 and the end portions of the drain electrodes 175, respectively. The passivation layer 180 and the gate insulating layer 140 have a plurality of contact holes 181 exposing the end portions 129 of the gate lines 121.

A plurality of pixel electrodes 191, and a plurality of contact assistants 81 and 82 that are preferably made of transparent conductor such as ITO or IZO or a reflective conductor such as Cr, Ag, Al, and alloys thereof, are formed on the passivation layer 180.

The pixel electrodes 191 are physically and electrically connected to the drain electrodes 175 through the contact holes 185 such that the pixel electrodes 191 receive the data voltages from the drain electrodes 175.

The description of the thin films 215 of the upper panel 200 will follow.

A light blocking member 220 called a black matrix for preventing light leakage and a plurality of color filters 230 are formed on the substrate 210. The color filters 230 may represent one of the primary colors such as red, green, and blue colors, and an overcoat 250 for preventing the color filters 230 from being exposed and for providing a flat surface is formed on the color filters 230 and the light blocking member 220. A common electrode 270 preferably made of a transparent conductive material such as ITO and IZO is formed on the overcoat 250.

A description of the electrophoretic layer 4 will follow with reference to FIG. 2.

The electrophoretic layer 4 includes a binder 310 and a plurality of electrophoretic members 330. The electrophoretic members 330 are dispersed in the binder 310, and the binder 310 determines the positions of the electrophoretic members 330 between the two panels 100 and 200.

The electrophoretic members 330 include a dispersion medium 328, electrophoretic particles 323 and 326, and capsules 320.

The electrophoretic particles 323 and 326 are dispersed and fixed in the dispersion medium 328, and include electrophoretic particles 323 having a negative charge and electrophoretic particles 326 having a positive charge.

Capsules 320 encapsulate the electrophoretic particles 323 and 326.

The electrophoretic particles 323 having the negative charge may represent a black color, and the electrophoretic particles 326 having the positive charge may represent a white color, but this may be varied. The electrophoretic particles 326 may represent at least one color of blue, green, and blue instead of the white color, and the color filters 230 may be omitted in this case.

Upon application of the common voltage to the common electrode 270 and a data voltage to the pixel electrodes 191, an electric field substantially perpendicular to the surfaces of the panels 100 and 200 is generated. Positions of the electrophoretic particles 323 and 326 are changed in response to the electric field generated between the pixel electrodes 191 and the common electrode 270, and the positions of the electrophoretic particles 323 and 326 may be changed by controlling the time that the electric field is maintained.

The brightness is changed according to the vertical distributions. When the electrophoretic particles 326 representing the white color move toward the common electrode 270, a white image is displayed, and when the electrophoretic particles 323 representing the black color move toward the common electrode 270, a black image is displayed. Therefore, the desired images may be represented by controlling the time that the data signals is applied.

In this embodiment, the thin films 115 and 215 are formed by formation and patterning of the conductive layers, the semiconductor layers, and the insulating layers, the formation processes are executed by physical vapor deposition and chemical vapor deposition, and the patterning is executed by lithography and etching processes using a photoresist layer.

When forming the thin films 115 shown in FIGS. 19 and 20, a total of seven formation processes and four patterning processes are needed, such as the deposition and patterning of the conductive layer for forming the gate lines 121, the deposition of the gate insulating layer 140, the deposition and patterning of the three layers for forming the semiconductors 151, the ohmic contacts 161 and 163, and the data lines 171 and the drain electrodes 175, the deposition for forming the passivation layer 180 and the patterning of the passivation layer along with the gate insulating layer 140 for forming the contact holes 181, 182, and 185, and the deposition and patterning of the conductive layer for forming the pixel electrodes 191 and the contact assistants 81 and 82.

When forming the thin films 215 shown in FIGS. 19 and 20, the formation and the patterning of the insulating layer (conductive layer) for forming the light blocking member 220, the formation and the patterning of color filters for forming the color filters 230, and the formation and the patterning for forming the overcoat 250 and the common electrode 270 are needed. As shown in FIGS. 3 to 20, because the overcoat 250 and the common electrode 270 are disposed in the predetermined region, the patterning for forming the overcoat 250 and the common electrode 270 is executed. Therefore, if the overcoat 250 and the common electrode 270 are formed by the conventional method, the patterning processes for forming the overcoat 250 and the common electrode 270 may be omitted.

On the other hand, the upper substrate 210 may be omitted in FIGS. 1 and 2. For example, an organic light emitting display device (OLED) using an organic light emitting material as the electro-optical active layer 3 may not include the upper substrate 210. In this case, the thin films 60 of FIGS. 3 to 20 may all include the thin film elements 115 and 215, and the electro-optical active layer 3.

According to the present invention, misalignment of the thin films due to deformation of the plastic substrate may be prevented such that the production time may be minimized, thereby improving the productivity of the display device.

While the present invention has been described in detail with reference to the preferred embodiments, those skilled in the art will appreciate that various modifications and substitutions can be made thereto without departing from the spirit and scope of the present invention as set forth in the appended claims.

What is claimed is:

1. A method of manufacturing a display device, the method comprising:
forming a buffer layer on a supporting plate;
forming a flexible substrate layer on the supporting plate and the buffer layer;
forming at least one thin film on the flexible substrate layer;
forming a protective layer covering the at least one thin film;
forming a plurality of through-holes to expose the buffer layer;
removing the buffer layer by injecting an etchant into the through-holes;
removing the protective layer; and
separating the flexible substrate layer from the supporting plate.

2. The method of claim 1, further comprising:
forming an etch promotion layer before forming the buffer layer.

3. The method of claim 2, wherein forming the through-holes further comprises forming a plurality of through-holes to expose the etch promotion layer.

4. The method of claim 2, wherein removing the buffer layer further comprises removing the etch promotion layer.

5. The method of claim 2, wherein the etch promotion layer comprises a highly polymerized compound having a gelation or swelling characteristic.

6. The method of claim 5, wherein the highly polymerized compound comprises at least one of polyethylene and polyvinylchloride.

7. The method of claim 2, wherein the etch promotion layer includes air gaps.

8. The method of claim 7, wherein the etch promotion layer comprises at least one of polyallyamine, polydiallyldiethyl ammonium chloride, polyacrylic acid, polyimide, polystyrene, and a urethane polymer.

9. The method of claim 2, wherein forming the etch promotion layer comprises:
forming a mixture of at least two polymers that are not dissolved by each other;
coating the mixture on the supporting plate;
hardening the coated mixture; and
removing one of the polymers by using a solvent that dissolves at least one of the polymers.

10. The method of claim 2, wherein forming the etch promotion layer comprises:
coating a solvent including inorganic matter particles and a on the supporting plate; and
sintering the solvent at a low temperature.

11. The method of claim 10, wherein the inorganic matter particles include at least one of titanium dioxide (TiO₂), indium tin oxide (ITO), indium zinc oxide (IZO), an azo group, and GaOₓ.

12. The method of claim 2, wherein forming the etch promotion layer comprises:
sequentially forming polyacrylic and polyallylamine on the supporting plate; and
exposing the supporting plate to an acidic vapor.

13. The method of claim 2, wherein forming the etch promotion layer comprises the deposition of a urethane polymer on the supporting plate by sputtering.

14. The method of claim 2, wherein forming the etch promotion layer comprises:
coating a highly polymerized compound having a gelation or swelling characteristic and a highly polymerized compound having absorptiveness and solubility; and
only dissolving the highly polymerized compound having absorptiveness and solubility.

15. The method of claim 1, wherein the protective layer comprises a photosensitive material.

16. The method of claim 1, wherein the buffer layer comprises a transparent conductive layer including ITO, IZO, or a-ITO.

17. The method of claim 16, wherein a thickness of the buffer is in a range of from about 100 to about 1000 angstroms.

18. The method of claim 1, wherein a thickness of the flexible substrate layer is in a range of from about 10 to about 200 microns.

19. The method of claim 1, wherein the through-holes are formed using a laser.

20. The method of claim 1, further comprising:
removing a circumferential portion of the flexible substrate layer before separating the flexible substrate layer from the supporting plate.

21. The method of claim 20, wherein removing a circumferential portion of the flexible substrate comprises irradiating a laser beam on the flexible substrate in a direction which is perpendicular to a surface of the supporting plate.

22. The method of claim 1, wherein the supporting plate is soaked in a bath including an etchant for etching the buffer layer

23. A method of manufacturing a display device, the method comprising:
forming a buffer layer having an upper surface, a lower surface, and side surfaces on a supporting plate;
forming a flexible substrate layer on the supporting plate and the buffer layer;
forming at least one thin film on the flexible substrate layer;
removing the buffer layer by contacting one of the upper, lower, and side surfaces with an etchant; and
separating the flexible substrate layer from the supporting plate.

24. The method of claim 23, further comprising:
forming a thin film that absorbs the etchant on at least one of the upper and lower surfaces.

25. The method of claim 24, wherein a speed of absorbing the etchant by the thin film is faster than a speed of absorbing the etchant by the side surfaces of the buffer layer.
